(19) United States
(12) Patent Application Publication
(10) Pub. No.: US 2014/0285231 A1
(43) Pub. Date: Sep. 25, 2014

(54) SEMICONDUCTOR DEVICE AND TRIMMING METHOD FOR THE SAME

(71) Applicant: Kabushiki Kaisha Toshiba, Tokyo (JP)

(72) Inventors: Yasuhiro SUEMATSU, Kanagawa (JP); Masaru KOYANAGI, Tokyo (JP); Satoshi INOUE, Kanagawa (JP); Yuui SHIMIZU, Kanagawa (JP)

(73) Assignee: KABUSHIKI KAISHA TOSHIBA, Tokyo (JP)

(21) Appl. No.: 14/017,289

(22) Filed: Sep. 3, 2013

(30) Foreign Application Priority Data
Mar. 22, 2013 (JP) 2013-060655

(51) Int. Cl. H03K 19/0175

(52) U.S. Cl. CPC H03K 19/017545
USPC 326/30

(57) ABSTRACT

According to one embodiment, a semiconductor device includes a termination circuit and a controller. The termination circuit includes a first resistor connected to an external connection terminal, a plurality of first transistors of a first conductive type connected in parallel between the first resistor and a voltage source, a second resistor connected to the external connection terminal, and a plurality of second transistors of a second conductive type connected in parallel between the second resistor and ground. The controller is configured to control switching of the first and second transistors such that a combined resistance value of the first and second resistors and the termination circuit is constant.

### CROSS-REFERENCE TO RELATED APPLICATION

This application is based upon and claims the benefit of priority from Japanese Patent Application No. 2013-060655, filed Mar. 22, 2013, the entire contents of which are incorporated herein by reference.

### FIELD

Embodiments described herein relate generally to an on die termination (ODT) circuit in a semiconductor device such as an NAND flash memory.

### BACKGROUND

An ODT circuit that is used in a semiconductor device can improve signal characteristics of the semiconductor device by reducing signal reflection in an input/output pin of the semiconductor device. Such an ODT circuit generally includes termination resistors and transistors.

The termination resistors are formed of metal wires, and resistance values of the metal wires vary in accordance with manufacturing process of the metal wires. With such a variation in the resistance values, obtaining uniform characteristics of the ODT circuits is difficult.

### DESCRIPTION OF THE DRAWINGS

FIG. 1 is a circuit diagram showing termination circuits included in a semiconductor device according to an embodiment.

FIG. 2 is a table illustrating combined resistance values of each of the termination circuits and combined resistance values of all the termination circuits shown in FIG. 1.

FIG. 3 illustrates an example of a semiconductor memory device including the semiconductor device according to the embodiment.

### DETAILED DESCRIPTION

In general, embodiments are directed to trimming of the resistance values of the termination resistor and thereby obtaining ODT circuits with uniform characteristics.

According to embodiments, a semiconductor device includes first and second termination circuits, each including a first resistor connected to an external connection terminal, a plurality of first transistors of a first conductive type connected in parallel between the first resistor and a voltage source, a second resistor connected to the external connection terminal, and a plurality of second transistors of a second conductive type connected in parallel between the second resistor and ground. The first termination circuit is activated when a tolerance of a combined resistance value of the first and second resistors is in a first range. The second termination circuit is activated when a tolerance of a combined resistance value of the first and second resistors is in the first range or a second range.

In a termination circuit, resistors are connected between an input/output pin and a power supply end, and between the input/output pin and the ground, for example. In an ODT circuit, MOS transistors and metal wires are connected between an input/output pin and a power supply end, and between the input/output pin and the ground, and a termination resistor is formed by the resistance of the MOS transistors and the wiring resistance of the metal wires. The MOS transistors are used for ON/OFF control of the ODT circuit. The ODT circuit is required to have a combined resistance value that is within a range determined in accordance with the design of the ODT circuit.

However, the combined resistance value of the ODT circuit may be out of the range in some cases due to the manufacturing process and temperature condition. In order to bring the combined resistance value of the ODT circuit within the range, trimming at least the fluctuating components due to the manufacturing process is preferable. However, these components are difficult to be trimmed only by adjusting the combined resistance value. For proper trimming, a ratio of the resistance value of the metal wires to the resistance value of the transistors needs to be maintained at 1.5 or larger. By increasing a proportion of the resistance value of the metal wires in the ODT circuit, linearity of I-V characteristics can be easily improved. In this case, however, there is a problem that the circuit size and the capacity of the pin increase.

An embodiment is hereinafter described with reference to the drawings.

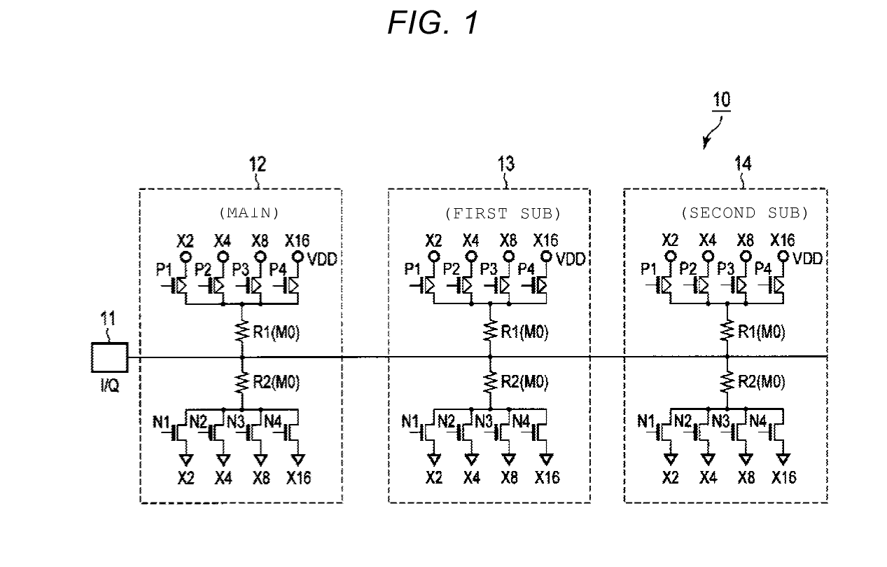

FIG. 1 illustrates an ODT circuit 10 according to this embodiment. Basically, in the case of trimming for the resistance value of the metal wires according to this embodiment, a total resistance value including the resistance value of the metal wires is adjusted using the ODT circuit 10. According to this embodiment, therefore, three Thevenin termination circuits (hereinafter referred to as termination circuits) 12, 13, and 14 are connected with an input/output pin (hereinafter referred to as an IO pin) 11, which is provided as an external connection terminal, as illustrated in FIG. 1.

Each of the three termination circuits 12, 13, and 14 has four P-channel MOS transistors (hereinafter referred to as PMOS transistors) P1, P2, P3, and P4, four N-channel transistors (hereinafter referred to as NMOS transistors) N1, N2, N3, and N4, and two resistors R1 and R2. Each of the resistors R1 and R2 is formed of a metal wire (M0) formed as a lowermost wiring layer of the semiconductor device, for example.

The three termination circuits 12, 13, and 14 have the same structure. Thus, the structure of the termination circuit 12 will be discussed on behalf of the three as follows.

One end of each PMOS transistors P1, P2, P3, and P4 in the current channels is connected with a power supply node to which a power supply voltage VDD is applied, while the other end of each of the transistors P1, P2, P3, and P4 is connected with one end of the resistor R1. The other end of the resistor R1 is connected with the IO pin 11.

The channel widths of the PMOS transistors P1, P2, P3, and P4 are set to values that are two times (×2), four times (×4), eight times (×8), and 16 times (×16), respectively, as large as a channel width of a reference PMOS transistor, in this embodiment.

The channel widths of the NMOS transistors N1, N2, N3, and N4 are set to values that are two times (×2), four times (×4), eight times (×8), and 16 times (×16), respectively, as large as a channel width of a reference NMOS transistor, in this embodiment.

One end of the resistor R2 is connected with the IO pin 11, while the other end of the resistor R2 is connected with one end of each of the NMOS transistors N1, N2, N3, and N4. The other end of each of the NMOS transistors N1, N2, N3, and N4 is grounded.

Switching of the PMOS transistors P1, P2, P3, and P4 and the NMOS transistors N1, N2, N3, and N4 is controlled based on trimming data stored in a ROM, for example, as will be described below. The PMOS transistors P1-P4 and the NMOS transistors N1-N4 have different channel widths, and therefore have different resistance values. Thus, a combined resistance value of selected (i.e., switched-on) transistors and the resistors R1 and R2 varies in accordance with switching of the PMOS transistors P1-P4 and the NMOS transistors N1-N4 based on the trimming data. Accordingly, the desired termination resistance value may be set by selecting appropriate transistors.

As described above, the ODT circuit is required to maintain a ratio of the resistance value of the metal wires to the resistance value of the MOS transistors at 1.5 or larger.

The three termination circuits 12, 13, and 14 function as a main termination circuit, a first sub-termination circuit, and a second sub-termination circuit, respectively. The termination circuits 12, 13, and 14 are hereinafter referred to as the main 12, the first sub 13, and the second sub 14 as well when appropriate.

As discussed above, the main 12, the first sub 13, and the second sub 14 have the same circuit structure, but the circuit sizes thereof are varied according to the trimming data. Assuming that the resistance value of the metal wires M0 varies within the range between −35% and +35% from a designed value due to a manufacturing error, the main 12 is driven when the resistance value varies in a range between −35% and −10%, the main 12 and the first sub 13 are driven when the resistance value varies in a range between −10% and +10%, and the main 12, the first sub 13, and the second sub 14 are simultaneously driven when the resistance value varies in a range between 10% and 35% for trimming the variation of the wiring resistance.

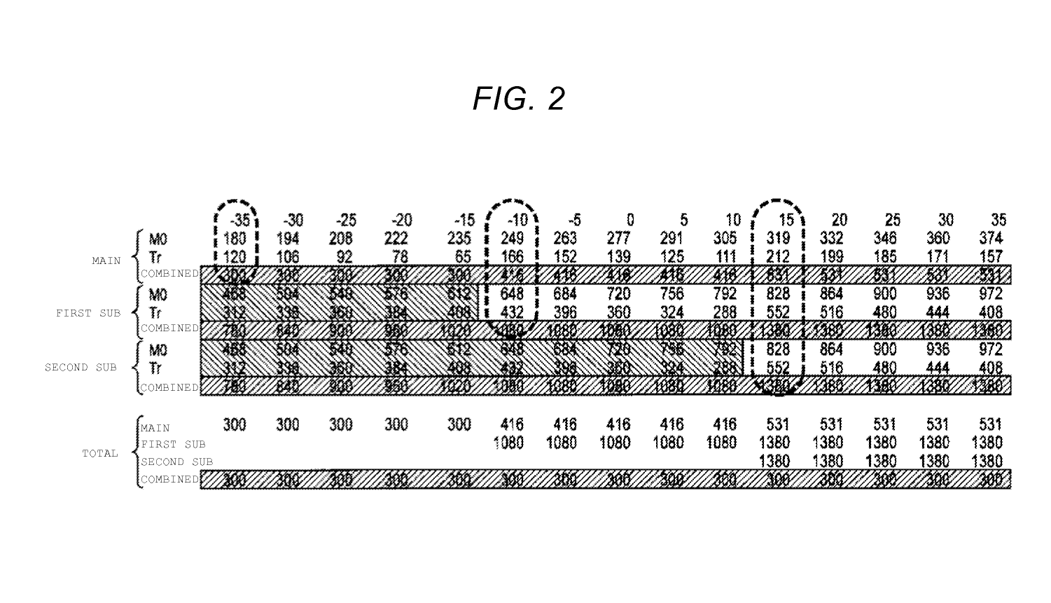

FIG. 2 shows a relationship between the variations produced in the manufacturing process, the resistance value of the metal wires M0 corresponding to the resistors R1 or R2, the resistance value of the PMOS transistors P1-P4 and the NMOS transistors N1-N4, and the combined resistance value thereof.

(1) When the variation of the resistance value of the metal wires M0 lies in the range between −35% and −10%, the main 12 is driven.

When the variation of the resistance value is −35%, for example, resistance value (M0) of the metal wires R1 and R2 of the main 12 becomes 180Ω, for example. In this case, one or more of the PMOS transistors P1-P4 and one or more of the NMOS transistors N1-N4 of the main 12 are selectively driven based on the trimming data, and controlled such that a combined resistance value of these transistors becomes 120Ω. As a result, a combined value of the resistance value of the metal wires and the resistance value of the PMOS transistors P1-P4 and the NMOS transistors N1-N4 is calculated as 180Ω+120Ω=300Ω.

In this condition, a ratio of a combined resistance value of the metal wires M0 to a combined resistance value of the PMOS transistors P1-P4 and the NMOS transistors N1-N4 is maintained at 3:2 or higher.

(2) When the variation of the resistance value of the metal wires M0 lies in the range between −10% and 10%, the main 12 and the first sub 13 are driven.

When the variation of the resistance value is −10%, for example, the resistance value (M0) of the metal wires R1 and R2 of the main 12 becomes 249Ω, for example. In this case, one or more of the PMOS transistors P1-P4 and one or more of the NMOS transistors N1-N4 of the main 12 are selectively driven based on the trimming data, and controlled such that the combined resistance value of these transistors becomes 166 Ω.

When the resistance value (M0) of the metal wires R1 and R2 of the first sub 13 is 648Ω, the PMOS transistors P1-P4 and the NMOS transistors N1-N4 of the first sub 13 are selectively driven based on the trimming data, and controlled such that the combined resistance value of these transistors becomes 432Ω.

As a result, the combined resistance value of the resistance value of the metal wires and the resistance value of the PMOS transistors P1-P4 and the NMOS transistors N1-N4 of the main 12, and of the first sub 13 become 416Ω and 1,080Ω, respectively. Therefore the parallel combined resistance value becomes 1/(1/416+1/1080)=300Ω.

In this condition, a ratio of the combined resistance value of the metal wires M0 to the combined resistance value of the PMOS transistors P1-P4 and the NMOS transistors N1-N4 with respect to the main 12 and the first sub 13 is each maintained at 1.5 or larger.

(3) When the variation of the resistance value of the metal wires M0 is in the range between 10% and 35%, variation of the wiring resistance is trimmed by simultaneously driving the main 12, the first sub 13, and the second sub 14.

When the variation of the resistance value is 15%, for example, the resistance value (M0) of the metal wires R1 and R2 of the main 12 becomes 319Ω, for example. In this case, one or more of the PMOS transistors P1-P4 and one or more of the NMOS transistors N1-N4 of the main 12 are selectively driven based on the trimming data, and controlled such that the combined resistance value of these transistors become 212Ω.

When the resistance value (M0) of the metal wires R1 and R2 of the first sub 13 is 828Ω, one or more of the PMOS transistors P1-P4 and one or more of the NMOS transistors N1-N4 of the first sub 13 are selectively driven based on the trimming data, and controlled such that the combined resistance value of these transistors become 552Ω.

When the resistance value (M0) of the metal wires R1 and R2 of the second sub 14 is 828Ω, one or more of the PMOS transistors P1-P4 and one or more of the NMOS transistors N1-N4 of the second sub 14 are selectively driven based on the trimming data, and controlled such that the combined resistance value of these transistors become 552Ω.

As a result, the combined resistance value of the resistance value of the metal wires and the resistance value of the PMOS transistors P1-P4 and the NMOS transistors N1N4 of the main 12, of the first sub 13, and of the second sub 14 become 531Ω, 1,380Ω, and 1,380Ω, respectively. Therefore the parallel combined resistance value becomes 1/(1/531+1/1380+1/1380)=300Ω.

In this condition, a ratio of the combined resistance value of the metal wires M0 to the combined resistance value of the PMOS transistors P1-P4 and the NMOS transistors N1-N4 with respect to the main 12, the first sub 13, and the second sub 14 are each maintained at 1.5 or larger.

While the variations of the resistance value are set at −35%, −10%, and 15% in the above examples, other variations of the resistance value are similarly trimmed such that the combined resistance value of the metal wires and the PMOS transistors P1-P4 and the NMOS transistors N1-N4 becomes 300Ω.

According to this embodiment, the three termination circuits 12, 13, and 14 are connected with the input/output pin 11 corresponding to the external connection terminal. The termination circuits 12, 13, and 14 each includes of plural PMOS transistors P1-P4, the NMOS transistors N1-N4, and the resistors R1 and R2, and the PMOS transistors P1-P4 and the NMOS transistors N1-N4 are controlled such that the combined resistance value of the resistors R1 and R2, the PMOS transistors P1-P4, and the NMOS transistors N1-N4 becomes a predetermined resistance value shown in the specifications, based on the trimming data created in correspondence with variations produced in the process of the resistors R1 and R2. According to this structure, appropriate trimming can be performed even when the resistance value of the resistors R1 and R2 used as the termination resistors varies in accordance with variations caused by the manufacturing process. Accordingly, the characteristics of the ODT circuit improve.

Moreover, a ratio of the combined resistance value of the resistors R1 and R2 to the combined resistance value of the PMOS transistors P1-P4 and the NMOS transistors N1-N4 may be maintained at 1.5 or larger in this embodiment. Accordingly, the linearity of the I-V characteristics of the ODT circuit improves without increasing the circuit size and the capacity of the pin.

According to this embodiment, each of the first sub 13 and the second sub 14 is not independently driven. Also, a combination of only the first sub 13 and the second sub 14, or of only the main 12 and the second sub 14 are not driven.

The trimming of the resistance value of the metal wires M0 according to this embodiment is an operation for decreasing the resistance value of the metal wires M0 by controlling the three parallel connections each constituted by the resistors R1 and R2 through adjustment of the operations of the main 12, the first sub 13, and the second sub 14 in the manner discussed above. Therefore, trimming for raising the resistance value of the metal wires M0 is not included in this embodiment. This is because the ON-resistance of switching transistors is difficult to be set to zero at the time of addition of the resistance value. The trimming for raising the resistance value of the metal wires M0 inevitably increases the circuit size and the capacity of the IO pin. According to the circuit in this embodiment, however, the ratio of the resistance value of the transistors to the resistance value of the metal wires M0 is maintained at 3:2 or higher, wherefore size increase of the transistors can be avoided.

The structures of the main 12, the first sub 13, and the second sub 14 are not limited to the structures shown in FIG. 1, but may be other structures. When the variations of the resistance value of the metal wires M0 caused by the manufacturing process are small and within a certain range of the values from a designed value, the second sub 14 may not be provided.

Each of the main 12, the first sub 13, and the second sub 14 includes four PMOS transistors and four NMOS transistors in this embodiment. However, the numbers of the transistors PMOS and NMOS are not limited to four.

According to the structure shown in FIG. 1, each of the main 12, the first sub 13, and the second sub 14 includes the two resistors R1 and R2, the four PMOS transistors, and the four NMOS transistors. However, the main 12, the first sub 13, and the second sub 14 may not have this structure. For example, each of the first sub 13 and the second sub 14 may have the two resistors R1 and R2, the one PMOS transistor, and the one NMOS transistor, while the main 12 has the structure shown in FIG. 1.

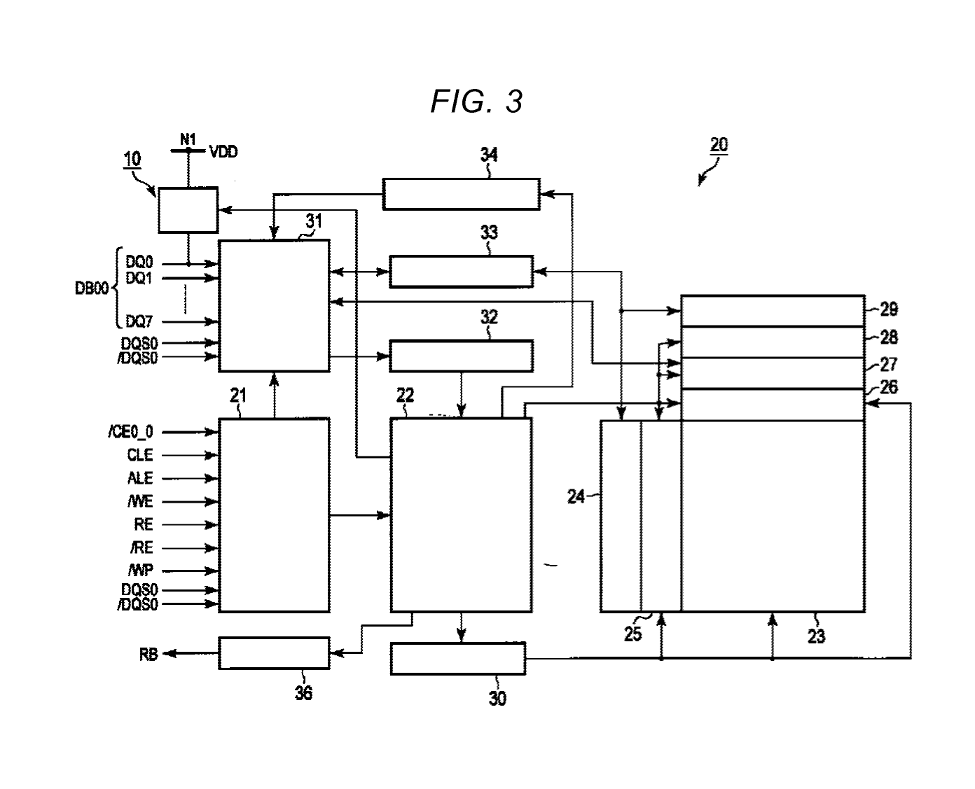

FIG. 3 shows an example of an NAND flash memory including the semiconductor device according to this embodiment.

An NAND flash memory 20 includes a logic controller 21, a controller 22, a memory cell array 23, a row address buffer 24, a row decoder 25, a sense amplifier 26, a data register 27, a column decoder 28, a column address buffer 29, a voltage generating circuit 30, an input/output (I/O) controller 31, a command register 32, an address register 33, a status register 34, an ODT circuit 35, and a ready/busy (R/B) circuit 36.

The logic controller 21 receives a chip enable signal/CE0_0, a command latch enable signal CLE, an address latch enable signal ALE, a write enable signal /WE, read enable signals RE and /RE, a write protect signal /WP, and clock signals DQS0 and /DQS0 output from a not-shown controller. The I/O controller 31 receives a command, an address, and data output from the controller via signal lines DQ0-DQ7 forming a data bus DB00. The I/O controller 31 also receives the clock signals DQS0 and /DQS0.

The logic controller 21 controls the controller 22 and the I/O controller 31 in accordance with the received signals. The command register 32 retains commands output from the I/O controller 31. The address register 33 retains addresses output from the I/O controller 31.

The controller 22 controls the row decoder 25, the sense amplifier 26, the data register 27, the column decoder 28, the voltage generating circuit 30, and the R/B circuit 36 in accordance with the commands retained in the command register 32 so as to control writing, reading, and deleting of data.

The R/B circuit 36 outputs a ready/busy signal RB in accordance with an output signal from the controller 22.

The voltage generating circuit 30 generates a writing voltage, a reading voltage, and a deleting voltage based on instructions from the controller 22, and supplies the generated voltages to the memory cell array 23, the row decoder 25, and the sense amplifier 26.

The memory cell array 23 has a plurality of not-shown NAND strings. Each of the NAND strings contains first and second selective transistors and a plurality of memory cells, which are connected in series. The first selective transistor is connected with a bit line, while the second selective transistor is connected with a source line. The gate electrodes of the first and the second selective transistors are connected with first and second selection lines respectively, while the control gate electrodes of the respective memory cells are connected with word lines. Each of the bit lines is connected with the sense amplifier 26.

The row address buffer 24 and the column address buffer 29 receive and retain the row address and the column address retained in the address register 33, respectively. The row decoder 25 decodes the row address retained in the row address buffer 24, and selects appropriate lines from the first and the second selection lines and the word lines of the memory cell array 23.

The column decoder 28 decodes the column address retained in the column address buffer 29, and selects appropriate lines from the bit lines of the memory cell array 23.

The data register 27 supplies the data received from the I/O controller 31 to the sense amplifier 26 at a timing of data writing. The data register 27 retains data detected from the selected bit lines by the sense amplifier 26 at a timing of data reading, and supplies the data to the I/O controller 31 at the timing of data reading.

The sense amplifier 26 writes the data retained in the data register 27 to the selected memory cell at the timing of the data writing. The sense amplifier 26 reads the data from the selected memory cell via the bit line at the timing of the data reading.

The status register 34 retains status data related to writing, reading, or deleting of data output from the controller 22 (e.g., whether the writing, reading, or deleting of the data is properly completed). The status data retained in the status register 34 is supplied to a host device 14 via the I/O controller 31, the data bus DB00, and the controller 13.

The ODT circuit 10 in this embodiment is connected with each of the data lines DQ0-DQ7 forming the data bus DB00, and the signal lines for transmitting signals of high bit rate, such as /RE, RE, DQS, and /DQS. FIG. 3 shows that the ODT circuit 10 is connected only with the data line DQ0 for convenience.

The PMOS transistors P1-P4 and the NMOS transistors N1N4 included in the ODT circuit 10 are controlled by the controller 22.

Furthermore, a not-shown replica circuit having the same structure as that of the ODT circuit 10 shown in FIG. 1 is provided in a chip containing the NAND flash memory 20. This replica circuit is tested by a tester, and the variation of the combined resistance value is trimmed with respect to each chip. Specifically, the variation caused by the manufacturing process is measured with respect to each chip to determine which of the ranges between −35% and −10%, between −10% and 10%, or between 10% and 35% the resistance value of the metal wires M0 is included in. Based on the determination result, the trimming data of the resistors R1 and R2, i.e., the control signals for the PMOS transistors P1-P4 and the NMOS transistors N1-N4 are determined with respect to each of the main 12, the first sub 13, and the second sub 14. The determined trimming data is stored in a ROM of each chip. The ROM is provided in a particular region within the memory cell array 23, for example. The trimming data stored in the ROM is read at a start timing of the NAND flash memory. The PMOS transistors P1-P4 and the NMOS transistors N1-N4 of the respective ODT circuits 10 are controlled based on the trimming data so that appropriate resistance value may be set.

According to this embodiment, the ODT circuit 10 is included in the NAND flash memory 20 as an application example. However, the ODT circuit according to this embodiment is applicable to other types of semiconductor devices such as a dynamic RAM as well as the NAND flash memory.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
first and second termination circuits each including a first resistor connected to an external connection terminal, a plurality of first transistors of a first conductive type connected in parallel between the first resistor and a voltage source, a second resistor connected to the external connection terminal, and a plurality of second transistors of a second conductive type connected in parallel between the second resistor and ground,
wherein the first termination circuit is activated when a tolerance of a combined resistance value of the first and second resistors is in a first range, and
wherein the second termination circuit is activated when a tolerance of a combined resistance value of the first and second resistors is in the first range or a second range.

2. The semiconductor device according to claim 1, wherein the first transistors have resistance values that are different from each other and the second transistors have resistance values that are different from each other.

3. The semiconductor device according to claim 2, wherein the resistance values of the first transistors are different from each other by a factor of two, and the resistance values of the second transistors are different from each other by a factor of two.

4. The semiconductor device according to claim 1, wherein a ratio of a combined resistance value of the first and second resistors to a combined resistance value of the first and second transistors is equal to or greater than 1.5.

5. A semiconductor device comprising:
a first termination circuit including a first resistor connected to an external connection terminal, a plurality of first transistors of a first conductive type connected in parallel between the first resistor and a voltage source, a second resistor connected to the external connection terminal, and a plurality of second transistors of a second conductive type connected in parallel between the second resistor and ground; and
a second termination circuit including a third resistor connected to the external connection terminal, at least one third transistor of the first conductive type connected between the third resistor and the voltage source, a fourth resistor connected to the external connection terminal, and at least one fourth transistor of the second conductive type connected between the fourth resistor and the ground,
wherein the first termination circuit is activated when a tolerance of a combined resistance value of the first through fourth resistors is in a first range, and
wherein the second termination circuit is activated when a tolerance of a combined resistance value of the first through fourth resistors is in the first range or a second range.

6. The semiconductor device according to claim 5, wherein
the first transistors have resistance values that are different from each other and the second transistors have resistance values that are different from each other.

7. The semiconductor device according to claim 6, wherein
the third transistors have resistance values that are different from each other and the fourth transistors have resistance values that are different from each other.

8. The semiconductor device according to claim 5, wherein the resistance values of the first transistors are different from each other by a factor of two, and the resistance values of the second transistors are different from each other by a factor of two.

9. The semiconductor device according to claim 8, wherein the resistance values of the third transistors are different from each other by a factor of two, and the resistance values of the fourth transistors are different from each other by a factor of two.

10. The semiconductor device according to claim 5, wherein
wherein a ratio of a combined resistance value of the first through fourth resistors to a combined resistance value of the first through fourth transistors is equal to or greater than 1.5.

11. A semiconductor device comprising:
a first termination circuit including a first resistor connected to an external connection terminal, a plurality of first transistors of a first conductive type connected in parallel between the first resistor and a voltage source, a second resistor connected to the external connection terminal, and a plurality of second transistors of a second conductive type connected in parallel between the second resistor and ground;
a second termination circuit including a third resistor connected to the external connection terminal, at least one third transistor of the first conductive type connected between the third resistor and the voltage source, a fourth resistor connected to the external connection terminal, and at least one fourth transistor of the second conductive type connected between the fourth resistor and the ground; and
a third termination circuit including a fifth resistor connected to the external connection terminal, at least one fifth transistor of the first conductive type connected between the fifth resistor and the voltage source, a sixth resistor connected to the external connection terminal, and at least one sixth transistors of the second conductive type connected between the sixth resistor and the ground,
wherein the first termination circuit is activated when a tolerance of a combined resistance value of the first through sixth resistors is in a first range, and
wherein the second termination circuit is activated when a tolerance of a combined resistance value of the first through sixth resistors is in the first range or a second range, and
wherein the third termination circuit is activated when a tolerance of a combined resistance value of the first through sixth resistors is in the first range, the second range, or a third range.
